(19) United States
(12) Patent Application Publication
(10) Pub. No.: US 2007/0218675 A1
(43) Pub. Date: Sep. 20, 2007

(54) Method for manufacturing bump of wafer level package

(76) Inventor: Chi-Long Tsai, Kaohsiung City (TW)

Correspondence Address: RABIN & Berdo, PC, 1101 14TH STREET, NW, SUITE 500, WASHINGTON, DC, 20005, US

(21) Appl. No.: 11/376,566

(22) Filed: Mar. 16, 2006

(30) Foreign Application Priority Data
Mar. 16, 2006 (TW) 094108079

(51) Int. Cl. H01L 21/44

(52) U.S. Cl. 438/613; 438/615; 438/674

(57) ABSTRACT

A method for manufacturing a bump of wafer level package is provided. First, a wafer with multiple pads and a passivation layer exposing the pads is provided, wherein the passivation layer between the pads has scribe lines for dividing chips after the package process. Next, a conducting layer is formed on the wafer, wherein the conducting layer is electrically connected to the pads and filled into the scribe line. Later, a photoresist layer is formed on the conducting layer. The photoresist layer is then patterned to form an opening exposing the conducting layer above the pads and to form at least one opening in the region outside the pads without exposing the conducting layer. Finally, a bump is formed in the opening above the pads to connect with the conducting layer.

### CROSS-REFERENCE TO RELATED APPLICATIONS

This non-provisional application claims priority under 35 U.S.C. § 119(a) on Patent Application No(s). 094108079 filed in Taiwan, R.O.C. on Mar. 16, 2005, the entire contents of which are hereby incorporated by reference.

### BACKGROUND OF THE INVENTION

1. Field of Invention

The present invention relates to a chip package process, and more particularly, to a method for manufacturing a bump of wafer level package.

2. Related Art

In the current highly informationized age, the market for integrated circuits is expanding continuously and conspicuously, and therefore integrated circuit package technology needs to go along with this development trend. To meet multiple-level requirements for integrated circuit elements, such as, high-speed processing capacity, multiple functions, integration, small size, light weight, and low price, integrated circuit package technology is also developed with a trend towards miniaturization and compactness. For example, the integrated circuit package technology currently used includes ball grid array (BGA), chip-scale package (CSP), and multi-chip module (MCM). In the integrated circuit package technology, the package density of the integrated circuit refers to the number of pins in each unit of area. As for high-density integrated circuit package, reducing the length of the wiring helps to accelerate the signal transmission speed. Therefore, the application of bumps has gradually become main stream in high-density packages.

Referring to FIGS. 1A to 1H, they show the flow charts for manufacturing a bump in the conventional chip package process. Firstly, a wafer 100 is provided, which has pads 101a and 101b and a passivation layer 103 for protecting the wafer 100 disposed thereon. A scribe line 105 can be formed between pads 101a and 101b for dividing chips after the chip package process. Next, an under bump metallurgy (UBM) 107 is formed on the wafer 100 to act as a joining interface between the sequentially-formed bumps and the pads. After forming the UBM 107, a photoresist 109 is formed on the wafer 100. The photoresist 109 is, for example, a dry film photoresist, which has multiple openings 111a and 111b at the region of pads 101a and 101 b acting as location for the subsequently-formed bumps. Then, multiple bumps 113a and 113b can be formed on the substrate after the steps of electroplating solders at the openings 111a and 111b, removing the photoresist layer, and the undesired UBM, and reflowing.

However, it should be noted that, in the step of electroplating solders into openings, the wafer is always flexed, even damaged, due to the stress from the solder squeezing the dry film photoresist layer on both sides, thus greatly reducing the reliability and yield of the chip package process.

### SUMMARY OF THE INVENTION

In view of the above problems, the present invention provides a method for manufacturing a bump of wafer level package. By forming the openings above the photoresist layer in the region outside the pads without exposing the conducting layer, the stress produced by solders on both sides can be relieved, so that reliability of the chip package process is enhanced, and the yield is improved.

Therefore, the method for manufacturing a bump of wafer level package disclosed by the present invention includes the following steps. First, a wafer with a plurality of scribe lines and a passivation layer formed thereon is provided, wherein a plurality of regions is defined between these scribe lines, and each of the regions includes a plurality of pads, and the passivation layer is disposed on each of regions to expose the plurality of pads. Then, a conducting layer is formed on the wafer, and the conducting layer is electrically connected to the pads and filled in the scribe lines. A photoresist layer is formed on the conducting layer. The photoresist layer is patterned to form a plurality of openings above the pads exposing the conducting layer and form a plurality of openings in the region outside the pads without exposing the conducting layer. Finally, a plurality of bumps is formed in the openings above the pads to connect the conducting layer.

The step of forming a plurality of openings above the regions outside the pads without exposing the conducting layer can be carried out through laser scribing, scribing through a heated cutting machine, exposure controlling, or double exposure and development.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIGS. 1A to 1H are flow charts for manufacturing a bump in the conventional chip package process; and

FIGS. 2A to 2H are manufacturing flow charts for a preferred embodiment of a method for manufacturing a bump of wafer level package according to the present invention.

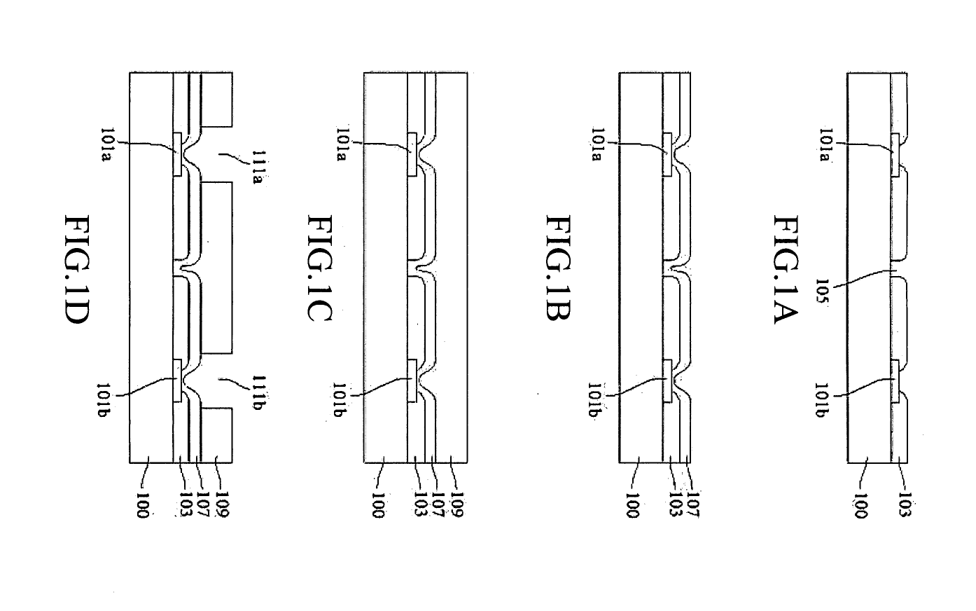

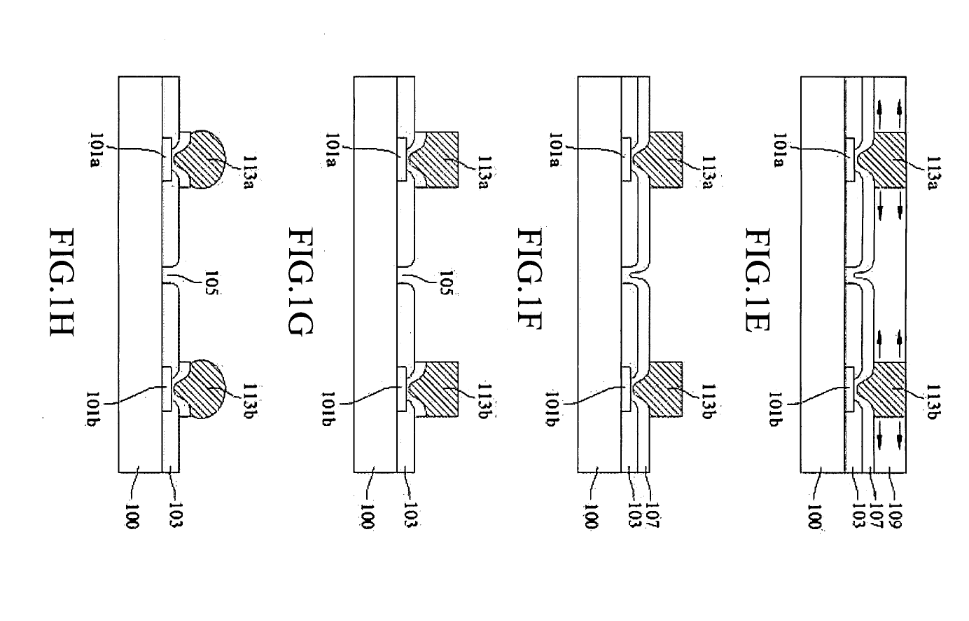

### DETAILED DESCRIPTION OF THE INVENTION

To further understand objects, structures, features, and functions of the present invention, the detail description is given below in conjunction with the embodiment. The above-mentioned description concerning the summary of the present invention and the following embodiments are used for exemplifying and explaining the principle of the present invention, as well as further interpreting claims of the present invention.

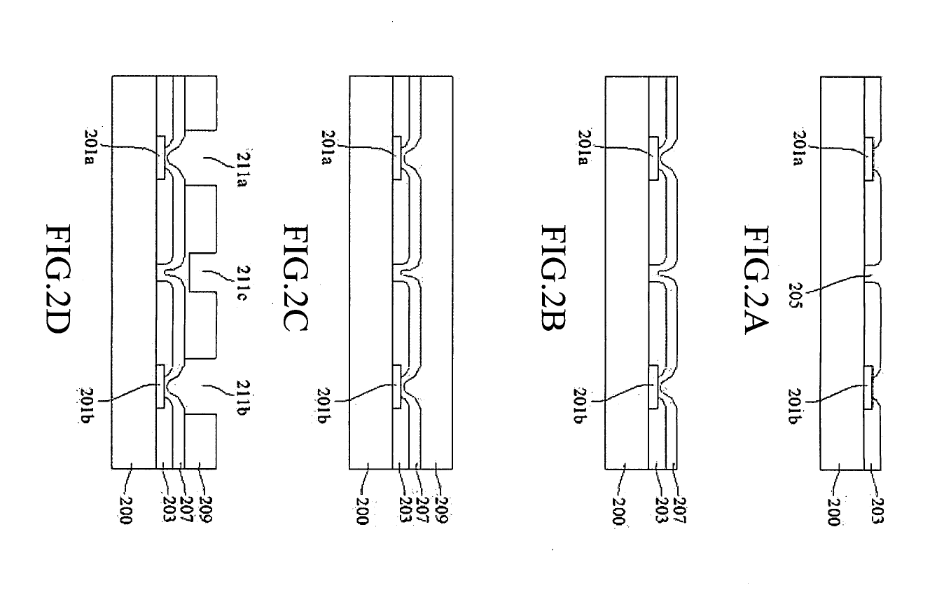

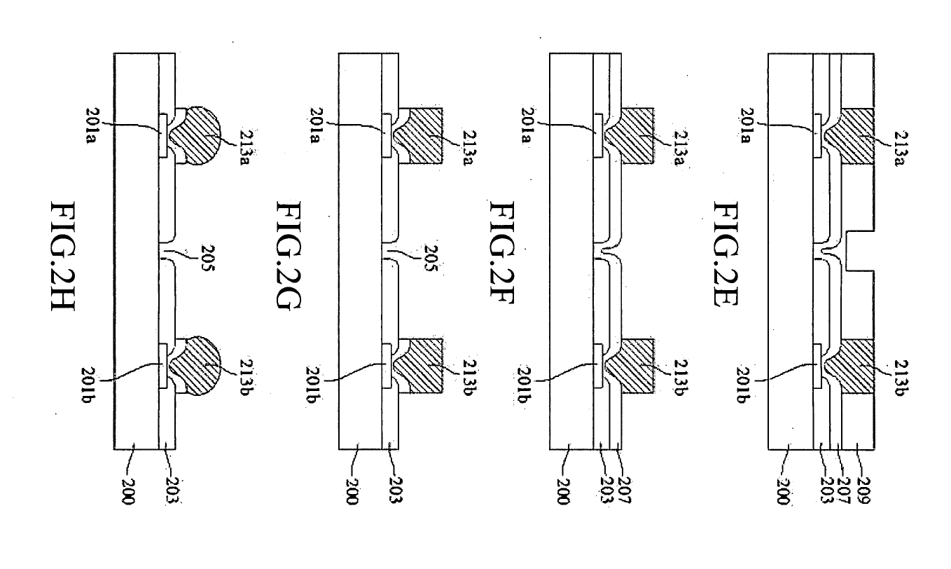

Referring to FIGS. 2A to 2H, they are manufacturing flow charts of a preferred embodiment of a method for manufacturing a bump of wafer level package according to the present invention.

As shown in FIG. 2A, a wafer 200 with pads 201a, 201b and a passivation layer 203 formed thereon is provided, wherein the passivation layer 203 is disposed on the surface of the wafer 200 for protecting the surface of the wafer 200 and exposing the pads 201a and 201b. Furthermore, the passivation layer 203 between the pads 201 and 204 can be provided with a scribe line 205 for dividing the chips later.

The wafer 200 described above also can be a printed circuit board or a bearing plate for other packages.

The material of the above-mentioned passivation layer 203 can include nitride, silicon nitride, phosphosilicate glass (PSG), or silicon oxide.

As shown in FIG. 2B, a conducting layer 207 is formed on pads 201a and 201b of the wafer and filled in the scribe line 205. The conducting layer 207 can be formed by electroplating, and the material of the conducting layer 207 includes, for example, titanium, titanium-tungsten alloy, aluminum, nickel-vanadium alloy, nickel, copper, or chromium, or the conducting layer 207 can be a three-layer structure of titanium/nickel-vanadium alloy/copper or aluminum/nickel-vanadium alloy/copper; or a double-layer structure of titanium/copper; or a four-layer structure of aluminum/titanium/nickel-vanadium alloy/copper.

As shown in FIG. 2C, a photoresist layer 209 is formed on the top surface of the wafer 200 for covering the conducting layer 207. The photoresist layer 209 is, for example, a dry film photoresist layer.

As shown in FIG. 2D, the photoresist layer 209 is patterned to form openings 211a and 211b exposing the conducting layer 207 below corresponding to the positions of pads 201a, 201b, and to form at least one opening 211c in the region outside the pads without exposing the conducting layer 207. In the description and drawings of this preferred embodiment, the opening 211c corresponding to the scribe line 205 is taken as an example for illustration, and is not intended to limit the present invention.

The opening 211c can be formed through scribing by laser or heated cutting machines, or the exposure controlling also can be used to make the opening 211c shallower, or double exposure and development also can be used, wherein a first exposure is utilized for exposing and developing the photoresist layer above the pads, and a second exposure is utilized for exposing and developing the photoresist layer above the region outside the pads. Besides, the second exposure is smaller than the first exposure. Alternately, at the first exposure and development, the openings in the region corresponding to pads and in the region outside the pads without exposing the conducting layer below are formed; the second exposure and development is directed to forming the openings in the region corresponding to the pads to completely expose the conducting layer below.

As shown in FIG. 2E, the solders are filled in the openings 211a and 211b above the pads to form the solder bumps 213a and 213b. The solders are filled through, for example, an electroplating process. The solder, for example, includes tin-lead metal.

As shown in FIGS. 2F to 2H, the photoresist layer 209 is removed, and the solder bumps 213a and 213b act as masks to remove the unnecessary conducting layer. Finally, the reflow process is carried out, so that the solder bumps are formed into a spherical shape, and fixed on the conducting layer 207.

In view of the above, in the steps of forming the opening in the photoresist layer, the opening in the region outside the pads without exposing the conducting layer is formed, such that spaces are provided for reliving the stress produced when solder bumps are formed by filling the openings on both sides with solders. Therefore, the wafer is prevented from being flexed or even damaged, thus enhancing reliability of the chip package process and improving the yield.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for manufacturing a bump of wafer level package, comprising:
providing a wafer with a plurality of scribe lines and a passivation layer formed thereon, wherein a plurality of regions is defined between the scribe lines, and each of the regions includes a plurality of pads, and the passivation layer is disposed on each of regions to expose the plurality of pads;
forming a conducting layer on the wafer, the conducting layer being electrically connected to the pads and filled in the scribe lines;
forming a photoresist layer on the conducting layer;
patterning the photoresist layer to form a plurality of openings above the pads exposing the conducting layer and to form a plurality of openings in the region outside the pads without exposing the conducting layer; and
forming a plurality of bumps in the openings above the pads to connect with the conducting layer.

2. The method for manufacturing a bump of wafer level package according to claim 1, wherein the step of patterning the photoresist layer comprises:
exposing and developing the photoresist layer above the pads by a first exposure; and
exposing and developing the photoresist layer above the region outside the pads by a second exposure, wherein the second exposure is smaller than the first exposure.

3. The method for manufacturing a bump of wafer level package according to claim 1, wherein the step of patterning the photoresist layer comprises:
forming a plurality of openings without exposing the conducting layer by a first exposure and development procedure; and
forming a plurality of openings above the pads exposing the conducting layer by a second exposure and development procedure.

4. The method for manufacturing a bump of wafer level package according to claim 1, wherein the step of forming a plurality of openings above the regions outside the pads without exposing the conducting layer is carried out by laser scribing.

5. The method for manufacturing a bump of wafer level package according to claim 1, wherein the step of forming a plurality of openings above the regions outside the pads without exposing the conducting layer is carried out by scribing with a cutting machine.

6. The method for manufacturing a bump of wafer level package according to claim 5, wherein the cutting machines is a heated cutting machine.

7. The method for manufacturing a bump of wafer level package according to claim 1, wherein the step of forming the bumps comprises:
filling a plurality of solders into the openings above the pads to connect with the conducting layer; and
removing the photoresist layer to enable the solders to form into the bumps.

8. The method for manufacturing a bump of a wafer level package according to claim 7, wherein the step of forming the bumps further comprises:
removing the conducting layer that does not covered by the bumps; and
reflowing the bumps.

9. The method for manufacturing a bump of wafer level package according to claim 7, wherein the step of filling the solders is carried out by electroplating.

10. The method for manufacturing a bump of wafer level package according to claim 7, wherein the solders contain tin-lead metal.

11. The method for manufacturing a bump of wafer level package according to claim 1, wherein the material of the passivation layer includes nitride.

12. The method for manufacturing a bump of wafer level package according to claim 1, wherein the material of the passivation layer includes silicon nitride.

13. The method for manufacturing a bump of wafer level package according to claim 1, wherein the material of the passivation layer includes phosphosilicate glass.

14. The method for manufacturing a bump of wafer level package according to claim 1, wherein the material of the passivation layer includes silicon oxide.

15. The method for manufacturing a bump of wafer level package according to claim 1, wherein the material of the conducting layer is selected from the group consisting of titanium, titanium-tungsten alloy, aluminum, nickel-vanadium, nickel, copper, chromium, and any combination thereof.

16. The method for manufacturing a bump of wafer level package according to claim 1, wherein the photoresist layer is a dry film photoresist layer.
